(19) United States
(12) Patent Application Publication
(10) Pub. No.: US 2026/0367113 A1
(43) Pub. Date: Nov. 19, 2026

(54) PROBE HEAD COMPRISING A GUIDE WITH METALLIZATIONS AND METHOD USING IT

(71) Applicant: TECHNOPROBE S.P.A., Cernusco Lombardone (LC) (IT)

(72) Inventors: Stefano FELICI, Cernusco Lombardone (LC) (IT); Fabio MORGANA, Cernusco Lombardone (LC) (IT)

(73) Assignee: TECHNOPROBE S.P.A., Cernusco Lombardone (LC) (IT)

(21) Appl. No.: 19/136,464

(22) PCT Filed: Dec. 19, 2023
(86) PCT No.: PCT/EP2023/086628

§ 371 Date: Jun. 6, 2025

(30) Foreign Application Priority Data
Dec. 21, 2022 (IT) 102022000026205

(51) Int. Cl. G01R 1/073; G01R 1/067

(52) U.S. Cl. CPC G01R 1/07371; G01R 1/06722; G01R 1/06733; G01R 1/07357

(57) ABSTRACT

A probe head for testing a device under test includes a plurality of contact elements having a body extending between respective end portions adapted to contact respective contact pads, a guide having guide holes for housing a portion of the contact elements, and a conductive portion formed at the guide. The conductive portion includes a group of the guide holes and contact and short-circuit a corresponding group of contact elements housed in the guide holes and carry a given same type of signal, forming a given conductive domain. The conductive portion is divided into sub-portions, so that the given conductive domain is divided into conductive sub-domains. Each of the conductive sub-portions distributes the given same type of signal among the contact elements that are short-circuited by it separately from the other conductive sub-portions which can have from 2 to 50 contact elements.

### DESCRIPTION

### Field of Application

The present invention relates to a probe head adapted to perform the test of electronic devices integrated on a semiconductor wafer and the following description is made with reference to this field of application with the only purpose of simplifying the exposition thereof.

### Prior Art

As it is well known, a probe head is essentially a device adapted to electrically connect a plurality of contact pads of a microstructure, in particular an electronic device integrated on a semiconductor wafer, with corresponding channels of a testing apparatus which performs the functionality testing thereof, particularly the electrical one, or generically the test.

The test performed on integrated circuits serves in particular to detect and isolate defective circuits as early as in the production phase. Usually, the probe heads are thus used for the test of the circuits integrated on wafers before cutting and assembling them inside a chip containment package.

A probe head essentially comprises a plurality of movable contact probes retained by at least one pair of supports or guides which are substantially plate-like and parallel to each other. These plate-like supports are provided with suitable guide holes and are located at a distance from each other so as to create a free area or air gap for the movement and the possible deformation of the contact probes, which are usually formed by wires made of special alloys with good electrical and mechanical properties.

The contact probes generally extend between a first end portion, intended to contact the contact pads of the device under test, and a second end portion, intended to contact a space transformer or a printed circuit board (PCB) associated with the probe head.

In a more and more increasing number of applications, for example in high-frequency applications, at least one of the guides of the probe head has a conductive portion (in particular a metallization) with the purpose of electrically connecting specific groups of contact probes to each other, forming a common conductive plane for these groups of probes. It is thereby possible to improve the frequency performances of the probe head and to carry signals having a higher and higher frequency with a low noise, since, among the various advantageous aspects of this solution, the signal is distributed on several contact probes.

In particular, in accordance with known solutions, single conductive portions are formed, which have a large surface extension on the guide, for example in the form of metallizations extending on a face of the guide, which short-circuit a large number of contact probes with each other, thereby forming single large conductive domains, which has however the disadvantage of occupying much space on the guide, leaving little space for short-circuiting different types of contact probes with each other. There are in fact devices which provide a large number of power supply domains, and thus known solutions do not allow to easily form conductive portions for all said domains.

The technical problem of the present invention is to provide a probe head having such functional and structural features as to allow the limitations and drawbacks still affecting known solutions to be overcome, in particular which is able to easily manage various metallizations for different domains in a guide.

### SUMMARY OF THE INVENTION

The solution idea underlying the present invention is to devise a probe head which comprises various metallizations corresponding to various different domains on a guide, each of said domains being divided into a plurality of independent conductive sub-domains including a limited number of contact elements (for example contact probes, but possibly also pogo pins) which are short-circuited with each other; said number being suitably selected, for example between 2 and 50, even better between 4 and 10 and/or between 10 and 20. Conductive portions are thus formed, which are divided into separated and independent conductive sub-portions, so as to have on the guide enough space for alternating with each other sub-domains related to different signals (for example to different power supplies), since it is possible to arrange conductive sub-domains related to a different signal among various conductive sub-domains of a same signal.

Based on this solution idea, the above technical problem is solved by a probe head for testing a device under test, said probe head comprising a plurality of contact elements comprising a body extending between respective end portions, which are adapted to contact respective contact pads, at least one guide provided with guide holes for housing at least one portion of the contact elements, and at least one conductive portion formed at the guide, said conductive portion including at least one group of the guide holes and being configured to contact and thus short-circuit a corresponding group of contact elements which are housed in said group of guide holes and are intended to carry a given same type of signal, thereby forming a given conductive domain, wherein the conductive portion is divided into distinct conductive sub-portions which are separated from each other, so that said given conductive domain is divided into distinct conductive sub-domains, wherein each one of the conductive sub-portions is configured to distribute said given same type of signal among the contact elements that are short-circuited by it separately from the other conductive sub-portions, and wherein each conductive sub-portion comprises a number of contact elements from 2 to 50, and thus in a limited number.

More particularly, the invention comprises the following additional and optional features, taken individually or, if necessary, in combination.

According to an aspect of the present invention, each conductive sub-portion can comprise a number of contact elements from 4 to 20, more preferably from 10 to 20, although other ranges are not excluded.

According to an aspect of the present invention, the conductive sub-portions of the conductive portion can be electrically insulated from each other.

According to an aspect of the present invention, the conductive portion, and thus the respective conductive sub-portions, can be configured to carry a given power supply signal, thereby forming as a whole a given power supply domain.

According to an aspect of the present invention, the probe head can comprise at least one first conductive portion and one second conductive portion, said first conductive portion including and electrically connecting to each other the holes of a first group of the guide holes, said first group housing first contact elements, said second conductive portion including and electrically connecting to each other the holes of a second group of the guide holes, said second group housing second contact elements, wherein the first contact elements and the second contact elements are connectable with respective different sources to carry a respective different type of signal, and wherein the first conductive portion and the second conductive portion are divided into respective conductive sub-portions.

According to an aspect of the present invention, the probe head can comprise a plurality of conductive portions corresponding to different power supply domains, each one intended to carry a respective different power supply signal.

According to an aspect of the present invention, the probe head can further comprise conductive portions configured to carry ground signals and/or operating signals from/to the device under test.

According to an aspect of the present invention, sub-portions of a domain can be alternated with sub-portions of a different domain, which is adapted to carry a different type of signal, said alternated domains (which carry different signals, for example different power supplies) being electrically insulated from each other.

According to an aspect of the present invention, the at least one conductive portion can coat at least one portion of at least one wall of the guide holes, wherein preferably the whole wall of the holes is coated by the conductive portion.

According to an aspect of the present invention, the conductive portion (and thus the sub-conductive portions) can be arranged on a face of the guide.

According to an aspect of the present invention, said guide can be a lower guide or an intermediate guide of the probe head. The lower guide is the guide which is closest to the device under test and is arranged between said device under test and the intermediate guide, if any.

According to an aspect of the present invention, the conductive sub-portions can be separated by means of at least one non-conductive area so as not to allow the electrical connection therebetween and possibly not to allow the electrical connection with contact elements intended to carry different signals.

According to an aspect of the present invention, the at least one guide can optionally comprise at least one coating dielectric portion which covers said at least one non-conductive area.

According to an aspect of the present invention, the contact elements can be in the form of contact probes of the buckling beam type wherein the body has a deformation.

Alternatively, according to an aspect of the present invention, the contact elements can be in the form of pogo pins, the body comprising in this instance a casing and an elastic element arranged in said casing, said casing defining a first surface and a second surface, at least one of said surfaces being adapted to abut against the guide, the electrical connection between the contact elements and the conductive portion being a pressing contact by means of said first and/or second surface.

According to an aspect of the present invention, each conductive portion can comprise a number of conductive sub-portions from 2 to 10.

The present invention also relates to a method for testing electronic devices, comprising the steps of:
arranging a probe head of the type disclosed above;
contacting pads of a device under test and at the same time contacting pads of an interface board (such as a space transformer and/or a PCB) respectively by means of the first end portion and the second end portion of the contact elements of the probe head; and
circulating (delivering) a given type of signal to at least one of said contact elements (and therefore connecting—directly or indirectly—the conducive portion to a source delivering said signal, for example via a pad or group of pads but not limited thereto), said given type of signal circulating (being delivered) in each of said conductive sub-portions, each of said conductive sub-portions thus distributing said given same type of signal among the contact elements that are short-circuited by it separately from the other conductive sub-portions.

According to an aspect of the present invention, the given type of signal may be a power signal and the conductive portion, and thus the respective conductive sub-portions, can carry said given power supply signal, thereby forming as a whole a given power supply domain.

According to an aspect of the present invention, the probe head may comprise at least one first conductive portion and one second conductive portion (even more, without being limited by a specific number), said first conductive portion including and electrically connecting to each other the holes of a first group of the guide holes, said first group housing first contact elements, said second conductive portion including and electrically connecting to each other the holes of a second group of the guide holes, said second group housing second contact elements, the method further comprising the step of circulating (delivering) a first type of signal to at least one of the first contact elements (and therefore connecting—directly or indirectly—the first conducive portion to a first source delivering said signal, for example via a first pad or group of pads, but not limited thereto), for example a first power signal, and circulating (delivering) a second type of signal to at least one of the second contact elements (and therefore connecting—directly or indirectly—the second conducive portion to a second source delivering said signal, for example via a second pad or group of pads but not limited thereto), the second type of signal being different from the first type of signal, for example a second power signal or a ground signal, and wherein the first conductive portion is divided into conductive sub-portions in which the first type of signal circulates (is delivered), and the second conductive portion is divided into conductive sub-portions in which the second type of signal circulates (is delivered).

The features and advantages of the probe head according to the invention will be apparent from the following description of an exemplary embodiment thereof given by way of non-limiting example with reference to the attached drawings.

### BRIEF DESCRIPTION OF THE DRAWINGS

In the drawings:

FIG. 1 schematically shows a probe head according to an embodiment;

FIG. 2 is a top schematic view of a guide of the probe head according to an embodiment of the present invention;

FIG. 3 schematically shows a probe head according to an embodiment of the present invention, comprising different conductive portions for respective different domains;

FIG. 4 is a top schematic view of a guide of the probe head according to an embodiment of the present invention, comprising different conductive portions for respective different domains;

FIG. 5 is another top schematic view of a guide of the probe head according to an embodiment of the present invention, comprising different conductive portions for respective different domains; and

FIG. 6 schematically shows a probe head according to an alternative embodiment of the present invention.

### DETAILED DESCRIPTION

With reference to the figures, a probe head adapted to perform the test of electronic devices integrated on a semiconductor wafer made according to the present invention is globally and schematically indicated with 20.

It should be noted that the figures represent schematic views and are not drawn to scale, but instead they are drawn so as to emphasize the important features of the invention. Furthermore, in the figures, the different elements are schematically depicted, the shape thereof being changeable depending on the desired application. Furthermore, it should be noted that, in the figures, identical reference numbers refer to identical elements in terms of shape or function. Finally, special arrangements described in relation to an embodiment illustrated in a figure can also be used for the other embodiments illustrated in the other figures.

Furthermore, it is noted that, unless it is expressly stated to the contrary, process steps can also be inverted if necessary.

The probe head 20 is adapted to connect with an apparatus (not illustrated in the figures) to perform the test of electronic devices integrated on a semiconductor wafer 23, for example high-frequency devices.

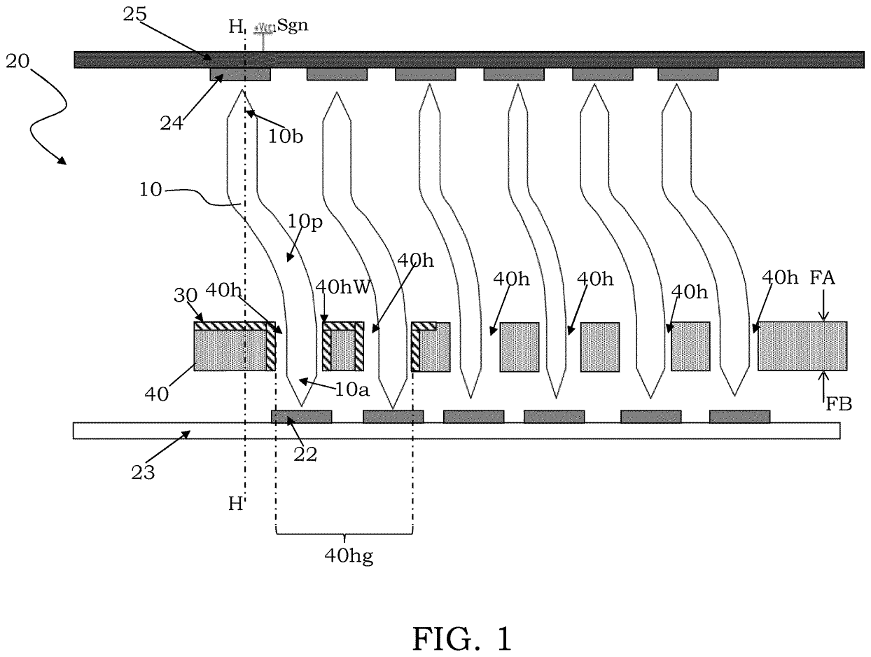

As illustrated in FIG. 1, the probe head 20 comprises a plurality of contact elements 10 which are slidingly housed in the probe head and intended to connect the device under test integrated on the semiconductor wafer 23 with the testing apparatus. In order to house the contact elements 10, the probe head 20 comprises at least one guide 40 provided with guide holes 40h through which said contact elements 10 are able to slide.

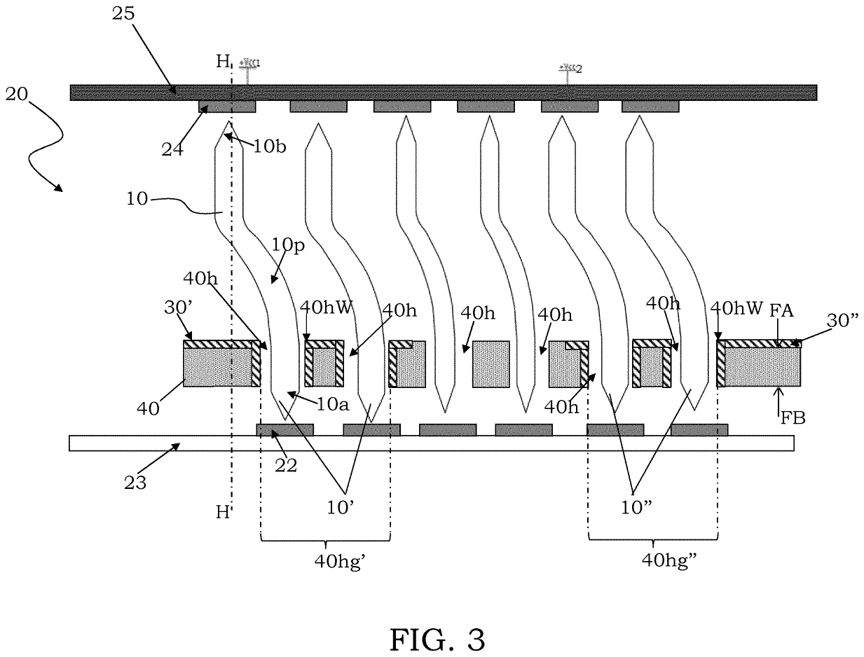

Each contact element 10 comprises a body 10p which extends along a longitudinal axis H-H between a first end portion 10a and a second end portion 10b, which are adapted to contact respective contact pads. By way of example, the first end portion 10a (also called contact tip) is adapted to contact contact pads 22 of the device under test integrated on the semiconductor wafer 23, while the second end portion 10b (also called contact head) is adapted to contact contact pads 24 of an interface board associated to the probe head 20 during the test, such as a space transformer or of a printed circuit board (PCB), this component being generically identified with the numeral reference 25. Clearly, although the end portions 10a and 10b in the attached FIGS. 1 and 3 end with a pointed shape, they are not limited thereto and can have any shape which is suited to the needs and/or circumstances.

In the embodiment shown in the figures, the guide 40 is a lower guide and thus, as it is known in the art, it is the guide which is closest to the first end portion 10a intended to contact the test device. In embodiments which are not illustrated in the figures, the guide 40 can also be an intermediate guide arranged above the lower guide (for example arranged between the lower guide and an upper guide, but generally closer to the first one). Thereby, as it will be seen below, the guide concerned by the present invention is the closest one to the device under test, contributing most to improving the frequency performances of the probe head.

In the embodiment of FIGS. 1 and 3, the body 10p has preferably a square or rectangular cross section (i.e. it is preferably rod-like), but the present invention is not limited thereto. For example, the body 10p can also have a circular section, or any other section suited to the needs and/or circumstances. In any case, the body 10p has at least one wall W, whose surface can be flat (for example in the case of a probe having a square or rectangular section) or curvilinear (for example in the case of a probe having a circular section), in contact with a respective wall of a guide hole.

In accordance with this embodiment of FIGS. 1 and 3, the contact element 10 is a contact probe of the type which is known in the art as “buckling beam”, i.e. it has a constant cross section for the whole length thereof, preferably a square or rectangular one, wherein the body 10p has a deformation in a substantially central position and is adapted to bend and thus to further deform during the test of the device under test.

The deformation of the body 10p is generally achieved by a so-called shifted plate guide configuration of the probe head 20, wherein a pair of guides is first overlapped so as to align the respective guide holes. Afterwards, once the contact probes 10 have been inserted into said guide holes, the guides are spaced apart, forming an air gap therebetween, and then they are shifted, causing the above deformation of the body 10p.

In this case, the contact probe 10 is able to further bend during the contact with the pads 22 of the device under test, said bending determining the lateral displacement of the probe in a certain direction, herein indicated as bending direction. In particular, the relative shift of the guides determines the bending direction of the contact probe 10 and thus the movement direction of the respective end portions. This movement causes at least one first wall of the contact probe 10 to contact a corresponding wall of a guide hole, a clearance being defined between a second wall of the contact probe 10 and an opposite wall of the guide hole, or both the opposite walls of the contact probe 10 may contact the corresponding opposite walls of the guide holes. In other words, during the bending, one or more walls W of the probe (in particular the two walls being opposite to each other along the bending direction) contact the walls of the guide holes in which the contact probe 10 is housed.

Furthermore, during the bending of the contact probes 10 (in particular during the vertical movement of the probes, indicated in the art as overtravel), a sliding contact occurs between the body 10p and the guide hole wall.

In this embodiment of FIGS. 1 and 3, the body 10p thus comprises a portion which is adapted to be at least partially inserted into a guide hole 40h of the lower guide 40 of the probe head 20 and, during the movement of the contact probe 10, it performs a contact with said guide hole 40h, in particular a sliding contact.

Hereafter in the present description, the contact elements 10 will thus be identified as contact probes; finally an example will be presented, in which the contact elements 10 are pogo pins, to which the same inventive concepts will however apply.

It is known in the art that the fixed position of the power supply and ground signals (due to the layout of the pads of the device under test) and the probe shape limit the control of the impedance of the signals inside the probe head. They also limit the control of the noise caused on the signal probes by other close signals, which limits the frequency performances of the probe head.

For this reason, in high-frequency applications (in particular RF applications), the power supply and also ground probes are short-circuited by means of a metallization on the guide, thereby short-circuiting probes of a same domain. Moreover, in the case of devices with different ground/power supply domains on the device which are then joined on the PCB, the metallization allows the loop inductance between a power supply and the related ground to be reduced.

Moreover, said metallizations allow the probe burning phenomenon to be reduced, especially for the case of power supply probes.

Consider the case in which a given power supply of a device under test is contacted by a probe of the probe head, which is short-circuited with other probes which carry power supply signals sharing the same power supply. Then, when the current of this power supply meets the metallization which short-circuits all the probes of this domain, it splits among all the short-circuited probes thereby allowing the inductance and equivalent resistance to be reduced compared to the case in which this current is confined in a single probe up to the PCB.

It is thus evident how the presence of metallizations on the guide, which short-circuit groups of probes and create a common conductive plane, allows the noise to be reduced and the frequency performances of the probe head to be increased.

For this purpose, in accordance with the present invention, the guide 40 of the probe head 20 comprises at least one conductive portion (indicated with the numeral reference 30) which includes and electrically connects the holes of at least one group (indicated with the reference 40hg) of the guide holes 40h and which is adapted to contact, and thus to short-circuit, a corresponding group of contact probes, which are intended to carry a same type of signal, in particular intended to carry a given ground or power supply or operating signal domain. Thereby, a given conductive domain is thus formed on the guide 40 which short-circuits probes adapted to carry a given signal, forming a common conductive plane in the probe head with a consequent increase in the probe head performances.

The Applicant has found that the contact elements 10 which are located at the ends of a conductive domain, in particular in the case of an extended domain with a large number of contact probes, do not significantly contribute to the above-indicated advantages, the contribution of the probes in a domain decreasing as a function of the distance, the same performances being hence obtained even with a limited number of probes in the domain.

In view of the above, advantageously according to the present invention, the above conductive portion 30 is divided into distinct conductive sub-portions (identified with the reference 30p) which are separated from each other, each of them including a limited number of contact probes, so that said given conductive domain is divided into smaller distinct conductive sub-domains.

In particular, each of the conductive sub-portions 30p is configured to distribute the given same type of signal (identified with the reference Sgn) among the contact elements 10 that are short-circuited by it separately from the other conductive sub-portions, thus forming conductive sub-portions (or conductive sub-domains) which are structurally independent and electrically insulated from each other.

The above conductive sub-portions 30p are thus independent, but they are however configured to carry the given same type of signal, for example a given power supply (but also ground signals and operating signals I/O, as detailed below).

In general, according to the present invention, there is thus at least one conductive portion 30 configured to form a common conductive plane for one of a power supply domain, a ground domain, or a set of contact probes 10 carrying a same operating signal I/O (without limitation as regards the type of carried signal), suitably divided into several conductive sub-portions 30p.

In a non-limiting example, the conductive portion 30, and thus the respective conductive sub-portions 30p, are configured to carry a given power supply signal, thereby forming as a whole a given power supply domain; each conductive sub-portion 30p thus carries said power supply separately from the other sub-portions.

Preferably, each conductive sub-portion 30p comprises a number of contact elements from 2 to 50.

However, there can be various ranges for the selection of the number of contact elements, for example from 2 to 100, the above-mentioned one from 2 to 50 (in general above 50, and, even more, above 100, the contribution of the added probes is minimum), from 2 to 20, from 2 to 10, or even from 4 to 50, from 4 to 20, from 4 to 10. A preferred range is between 4 and 20, even more preferred from 10 to 20.

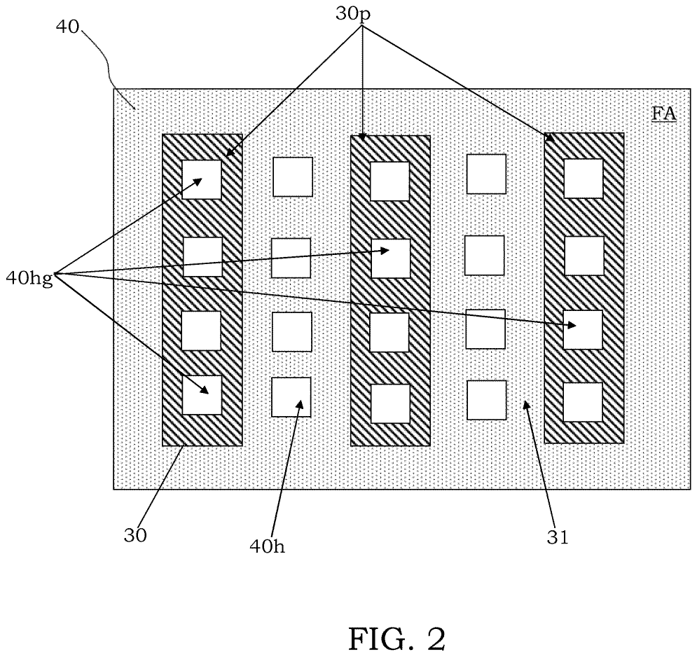

In an exemplary embodiment, as illustrated in FIG. 2 (which shows the various sub-portions 30p of a single given conductive domain), the conductive sub-portions 30p are separated from each other, and from other probes that are not to be short-circuited, by means of at least one non-conductive area 31 so as not to allow the electrical connection among them and not to allow the electrical connection with other contact probes intended to carry different signals. In a particular embodiment, the guide 40 optionally comprises at least one coating dielectric portion which covers the aforementioned non-conductive area 31.

As shown in FIG. 3, the probe head 20 can comprise any number of conductive portions 30 arranged in any way on the guide or even embedded therein, to carry any type of signal. FIG. 3 shows two different conductive portions, 30′ and 30″, intended to carry two different signals (for example two power supplies), but it is evident that all the drawings only represent indicative and non-limiting examples of the scope of the present invention, and any number and type of conductive portions can be adopted based on circumstances. Moreover, as indicated above the present invention can be applied to any type of signal, be it a ground, a power supply or an operating signal I/O, even in combination, adjusting the number and type of conductive portions based on circumstances.

More particularly, in the embodiment of FIG. 3, the probe head 20 comprises at least one first conductive portion 30′ and one second conductive portion 30″, where the first conductive portion 30′ includes and electrically connects to each other the holes of a first group 40hg′ of the guide holes 40h, said first group housing first contact elements 10′, while the second conductive portion 30″ includes and electrically connects the holes of a second group 40hg″ of the guide holes 40h, said second group housing second contact elements 10″.

The first contact elements and the second contact elements 10′ and 10″ are connectable with respective different sources to carry a respective different type of signal (for example two different power supplies, for example via one or more of the aforementioned pads), and, suitably according to the present invention, the first conductive portion 30′ and the second conductive portion 30″ are both divided into respective conductive sub-portions, in the above-illustrated mode.

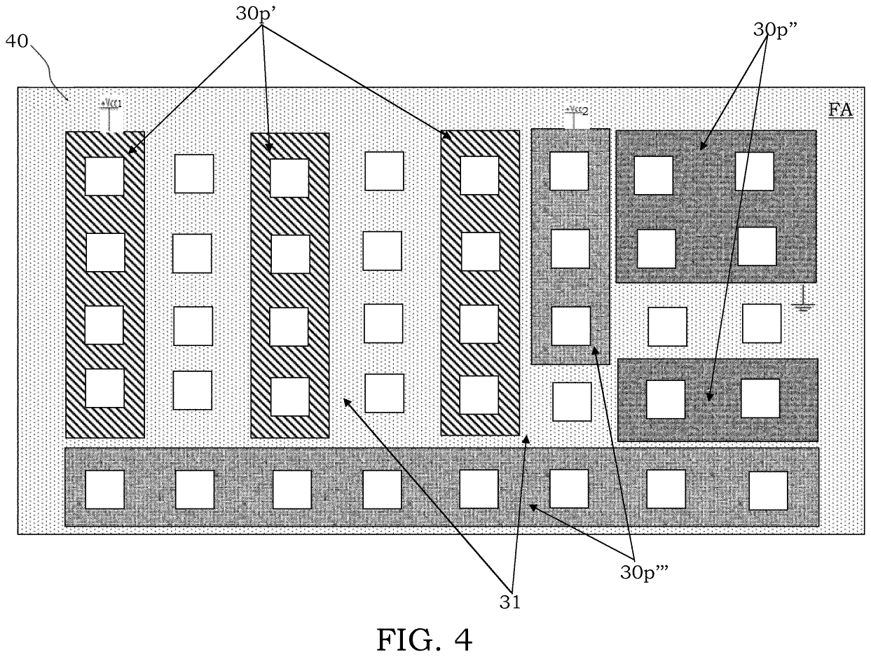

FIG. 4 shows a schematic example in which various conductive sub-portions related to different domains can be seen, specifically three different domains (where the respective sub-portions are indicated with references 30p′, 30p″ and 30p′″). For example, two domains can be related to two different power supplies while the third domain can be a ground domain, but obviously this is only a non-limiting example and the configuration (number, type and arrangement of the domains) can vary based on requirements and/or needs.

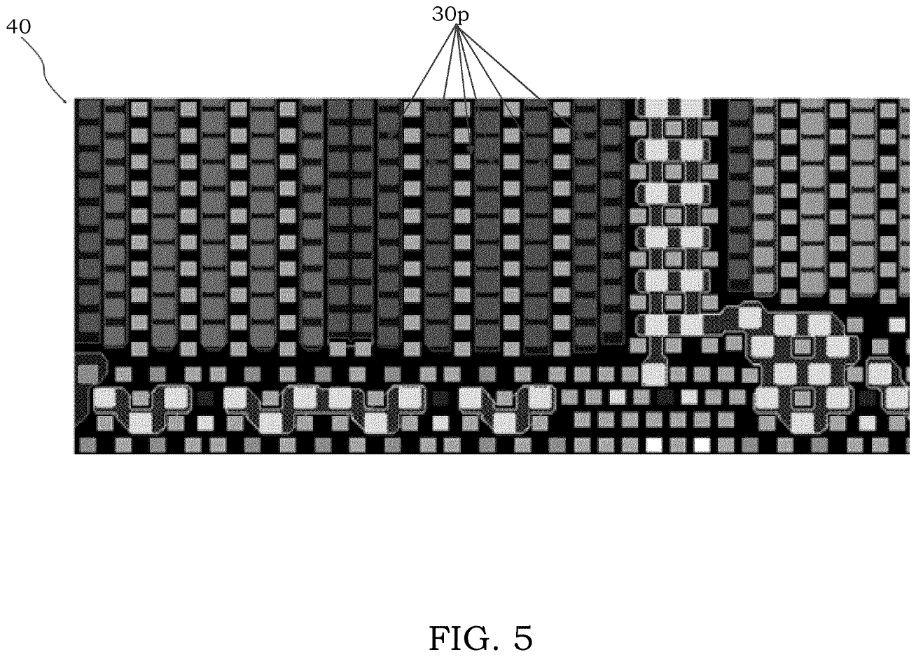

FIG. 5 shows an even more complex example, in which the various colors correspond to different domains, which are suitably divided and intertwined with each other. As illustrated in the figures, one of the advantages of the present invention is in fact the possibility to alternate conductive sub-portions of a domain with conductive sub-portions of a different domain (i.e. adapted to carry a different type of signal), said alternated domains being electrically insulated from each other forming a substantially puzzle-like configuration.

As mentioned, since the latest generation devices provide a large number of different power supplies, the probe head 20 can comprise a plurality of conductive portions corresponding to different power supply domains (in a number even exceeding ten), each one intended to carry a respective different power supply signal. Obviously, the above does not exclude even the presence of other types of domains, such as ground domains (which can be represented by grey squares in FIG. 5) or signal I/O ones (in the latter case for example for implementing the loop-back technique).

In an embodiment of the present invention, the conductive portion 30 can be formed on an upper face F1 of the guide 40 (as illustrated in the figures), as well as on a lower face F2 thereof, as well as it can be formed inside said guide.

Obviously, as indicated above, the present invention is not limited by the number and arrangement of the conductive portions, which can be set based on needs and/or circumstances, as described for example in the international patent application no. PCT/EP2017/082180 in the name of the Applicant.

As shown in FIGS. 1 and 3, the conductive portion 30 coats at least one portion of the walls 40hW of the guide holes of the group 40hg, thereby forming a metalized portion of the guide hole which contacts the contact probe 10, in particular with which the contact probe 10 performs the above sliding contact. Preferably, the conductive portion 30 can fully cover some or all the walls of the guide holes (and thus in this case the metalized portion coincides with the whole wall 40hW of the holes), or it is possible to provide a configuration in which said conductive portion 30 only partially covers the wall 40hW of the guide holes.

In any case, what matters is that the presence of the at least one conductive portion 30, being suitably divided, allows to form conductive domains which electrically connect contact probes with each other, increasing the performances of the probe head 20 as a whole and allowing very advantageous layouts for the guide 40, as shown above.

Furthermore, in accordance with embodiments of the present invention, each conductive portion 30 comprises a number of conductive sub-portions 30p from 2 to 10, but any suitable number can be adopted.

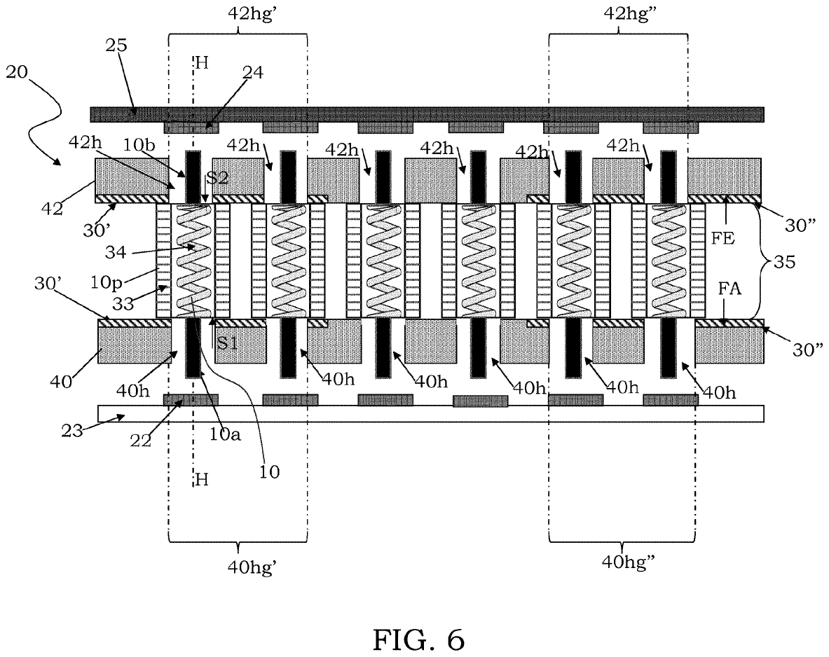

Finally, in an alternative embodiment of the present invention illustrated in FIG. 6, the contact elements 10 can be in the form of pogo pins. In this case, the body 10p comprises a casing 33 and an elastic element 34 arranged in the casing 33, which defines a first surface S1 and a second surface S2, said surfaces forming suitable shoulders for abutting against the guide of the probe head. As illustrated in FIG. 6, the probe head 20 can also comprise an upper guide 42 separated from the lower guide 40 by a gap 35, possibly comprising it too one or more conductive portions. Suitably, at least one of the surfaces S1 and S2 is adapted to abut against the guide (in this case generally both surfaces S1 and S2 on both guides 40 and 42), the electrical connection between said contact elements 10 and said at least one conductive portion 30 being a pressing contact by means of said first and/or second surface S1 and S2.

From the above considerations, it is clear that the present invention also relates to a method for testing electronic devices using the probe head 20, wherein all the technical features of the probe head 20 can be applied in this method. In an embodiment, during the test, the probe head is associated with an interface board and with a test equipment via said board, and signals are delivered to the probes (for example via different sources delivering signal through one or more pads, and therefore connecting—directly or indirectly—the conductive portions with said sources).

In conclusion, the present invention thus allows the technical problem to be successfully overcome, providing the above probe head and solving all the drawbacks of the prior art.

Advantageously according to the present invention, the single metallizations are finely divided, allowing very advantageous layouts on the guide of the probe head to be adopted. Thereby, even in the case of several different domains, it is possible to make all the metallizations on a single face of a guide, suitably alternating/intertwining the various sub-domains, which comprise in fact a limited number of probes.

Such a configuration is obtained without compromising on the frequency performances of the probe head; in other words, the division of a single domain into many sub-domains does not cause a loss of efficiency, while suitably allowing multiple different domains on a single guide to be easily managed.

It is thus evident that the probe head of the present invention is particularly suited to the test of high-frequency devices, also in the radiofrequency domain, for example high-frequency devices having multiple power supply domains.

Obviously, in order to meet contingent and specific requirements, a person skilled in the art will be allowed to bring several modifications and alternatives to the above-described probe head, all falling within the scope of protection of the invention as defined by the following claims.

1. A probe head for testing a device under test, said probe head comprising:
a plurality of contact elements comprising a body extending between respective end portions which are adapted to contact respective contact pads;
a guide provided with guide holes for housing a portion of the contact elements; and
a conductive portion formed at the guide, the conductive portion including at least one a group of said guide holes and being configured to contact and short-circuit a corresponding group of contact elements housed in said group of guide holes and intended to carry a given same type of signal, thereby forming a given conductive domain,
wherein the conductive portion is divided into distinct conductive sub-portions which are separated from each other, so that said given conductive domain is divided into distinct conductive sub-domains,
wherein each of the conductive sub-portions is configured to distribute said given same type of signal among the contact elements that are short-circuited by it separately from the other conductive sub-portions, and
wherein each conductive sub-portion comprises from 2 to 50 contact elements.

2. The probe head according to claim 1, wherein each conductive sub-portion comprises from 4 to 20 contact elements.

3. The probe head according to claim 1, wherein the conductive sub-portions of the conductive portion are electrically insulated from each other.

4. The probe head according to any claim 1, wherein the conductive portion and the respective conductive sub-portions, are configured to carry a given power supply signal, thereby forming as a whole a given power supply domain.

5. The probe head according to claim 1, further comprising a first conductive portion and a second conductive portion, said first conductive portion including and electrically connecting to each other the holes of a first group of the guide holes, said first group housing first contact elements said second conductive portion including and electrically connecting to each other the holes of a second group of the guide holes said second group housing second contact elements, wherein the first contact elements and the second contact elements are connectable with respective different sources to carry a respective different type of signal, and wherein the first conductive portion and the second conductive portion are divided into respective conductive sub-portions.

6. The probe head according to claim 5, further comprising a plurality of conductive portions corresponding to different power supply domains, each one intended to carry a respective different power supply signal.

7. The probe head according to claim 6, further comprising conductive portions configured to carry ground signals and/or operating signals from/to the device under test.

8. The probe head according to claim 5, wherein sub-portions of a domain are alternated with sub-portions of a different domain, said different domain being adapted to carry a different type of signal, said alternated domains being electrically insulated from each other.

9. The probe head according to claim 1, wherein the conductive portion is arranged on a face of the guide.

10. The probe head according to claim 1, wherein said guide is a lower guide or an intermediate guide of the probe head.

11. The probe head according to claim 1, wherein the conductive sub-portions are separated from each other by a non-conductive area so as not to allow the electrical connection among them and possibly not to allow the electrical connection with contact elements intended to carry different signals, and wherein said one guide optionally comprises a coating dielectric portion which covers said non-conductive area.

12. The probe head according to claim 1, wherein the contact elements are in the form of contact probes of the buckling beam type wherein the body has a deformation.

13. The probe head according to claim 1, wherein the contact elements are in the form of pogo pins, said body comprising a casing and an elastic element arranged in said casing said casing defining a first surface and a second surface, at least one of said surfaces being adapted to abut against the guide, the electrical connection between said contact elements and said conductive portion being a pressing contact by means of said first and/or second surface.

14. A method for testing electronic devices, comprising:
arranging a probe head according to claim 1;
contacting pads of a device under test and at the same time contacting pads of an interface board respectively by means of a first end portion and a second end portion of the contact elements of the probe head; and
circulating a given type of signal to at least one of said contact elements, said given type of signal circulating in each of said conductive sub-portions, each of said conductive sub-portions distributing said given same type of signal among the contact elements that are short-circuited by it separately from the other conductive sub-portions.

15. The method of claim 14, wherein the given type of signal is a power signal and the conductive portion, and the respective conductive sub-portions, carry said given power supply signal, thereby forming as a whole a given power supply domain.

16. The method of claim 14, wherein the probe head comprises a first conductive portion and a second conductive portion, said first conductive portion including and electrically connecting to each other the holes of a first group of the guide holes, said first group housing first contact elements, said second conductive portion including and electrically connecting to each other the holes of a second group of the guide holes, said second group housing second contact elements, the method further comprising the step of circulating a first type of signal to at least one of the first contact elements, for example a first power signal, and circulating a second type of signal to at least one of the second contact elements, the second type of signal being different from the first type of signal.

17. The probe head according to claim 2, wherein each conductive sub-portion comprises from 10 to 20 contact elements.

18. The method of claim 16, wherein the second type of signal is a second power signal or a ground signal, and wherein the first conductive portion is divided into conductive sub-portions in which the first type of signal circulates and the second conductive portion is divided into conductive sub-portions in which the second type of signal circulates.
